(19) United States
(12) Patent Application Publication
(10) Pub. No.: US 2021/0111709 A1
(43) Pub. Date: Apr. 15, 2021

(54) METHODS AND SYSTEM FOR A RESETTABLE FLIP FLOP

(71) Applicant: SEMICONDUCTOR COMPONENTS INDUSTRIES, LLC, Phoenix, AZ (US)

(72) Inventors: Manish Kumar VISHWAKARMA, Azamgarh (IN); Rajiv PANDEY, Bangalore (IN); Santosh Kumar PANIGRAHI, Bhubaneswar (IN)

(73) Assignee: SEMICONDUCTOR COMPONENTS INDUSTRIES, LLC, Phoenix, AZ (US)

(21) Appl. No.: 16/947,562

(22) Filed: Aug. 6, 2020

(30) Foreign Application Priority Data
Oct. 9, 2019 (IN) 201911040791

(51) Int. Cl. H03K 3/356; H03K 3/037; H03K 19/17736; H03K 19/094

(52) U.S. Cl. CPC H03K 3/35606; H03K 19/09432; H03K 19/1774; H03K 3/037

(57) ABSTRACT

Various embodiments of the present technology may comprise methods and system for a resettable flip flop. The flip flop may receive a clock signal along a first circuit path and a reset signal along a second circuit path. The first circuit path provides a first high voltage value and a first low voltage value, and the second circuit path provides a second high voltage value that is greater than the first high voltage value and a second low voltage value that is less than the first low voltage value.

### CROSS-REFERENCE TO RELATED APPLICATION

This application claims the benefit of Indian Provisional Patent Application No. 201911040791, filed on Oct. 9, 2019, the contents of which are incorporated by reference.

### BACKGROUND OF THE TECHNOLOGY

A flip flop is a basic building block for many digital designs and may be integrated into various applications, such as network switches, mobile/satellite communication systems, and fiber optic communication systems. The flip flop can be used for data sampling or frequency division. In applications where the flip flop is used for data sampling or frequency division, high performance (in GHz range) and low power consumption is desirable to extend battery lifetime in portable equipment and to reduce heat generation.

For some applications, it is necessary to define the state of the flip flops before it is used for data transfer or used as frequency divider. This can be achieved by providing a RESET input to define the state of the flip-flop to logic “LOW.” However to achieve the reset functionality, some conventional architectures require an additional AND gate stage, which increases the clock to output delay, thus adversely limiting the frequency performance and increasing power consumption.

In other conventional architectures, the voltage levels of the RESET input and the CLK/CLKB are set such that transistors in the flip flop that act as current sources will not get sufficient headroom to remain in the saturation region, which limits the high frequency performance and reduces design robustness across process, voltage, and temperature variations.

### SUMMARY OF THE INVENTION

Various embodiments of the present technology may comprise methods and system for a resettable flip flop. The flip flop may receive a clock signal along a first circuit path and a reset signal along a second circuit path. The first circuit path provides a first high voltage value and a first low voltage value, and the second circuit path provides a second high voltage value that is greater than the first high voltage value and a second low voltage value that is less than the first low voltage value.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 is a block diagram of a system in accordance with an exemplary embodiment of the present technology;

FIG. 2 is a circuit diagram of a first-type amplifier in accordance with an exemplary embodiment of the present technology;

FIG. 3 is a circuit diagram of a second-type amplifier in accordance with an exemplary embodiment of the present technology;

FIG. 4 is a circuit diagram of a reference voltage generator in accordance with an exemplary embodiment of the present technology;

FIG. 5 is a circuit diagram of a level shifter in accordance with an exemplary embodiment of the present technology;

FIG. 6 is a circuit diagram of a flip flop in accordance with an exemplary embodiment of the present technology;

FIGS. 7A-7C illustrate various input and output waveforms of a first circuit path in accordance with an exemplary embodiment of the present technology;

FIGS. 8A-8D illustrate various input and output waveforms of a second circuit path in accordance with an exemplary embodiment of the present technology; and

FIGS. 9A-9C illustrate the output behavior of a flip flop circuit used as a divider in accordance with an exemplary embodiment of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various switching devices, current sources, voltage sources, semiconductor devices, such as transistors, resistors, capacitors, and the like, which may carry out a variety of functions. In addition, the present technology may be integrated in any number of systems that feature data sampling and/or frequency division, such as network switches, mobile/satellite communication systems, fiber optic communication system, and the like.

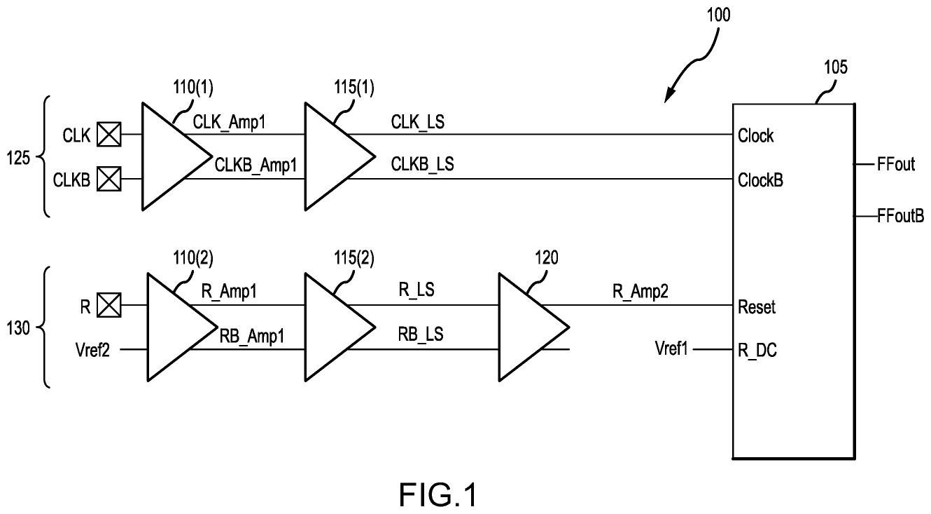

Referring to FIG. 1, the system 100 may be configured as a high-speed resettable current mode logic flip flop. In other words, the system 100 may operate at high speed in tune of 10 GHz (speed has technology dependency), have the ability to be reset, and operate according to current mode logic levels. In various embodiments, the system 100 may comprise a flip flop circuit 105 connected to a number of circuit paths configured to deliver various signals to the flip flop circuit 105. For example, in an exemplary embodiment, the system 100 may comprise a first circuit path 125 and a second circuit path 130.

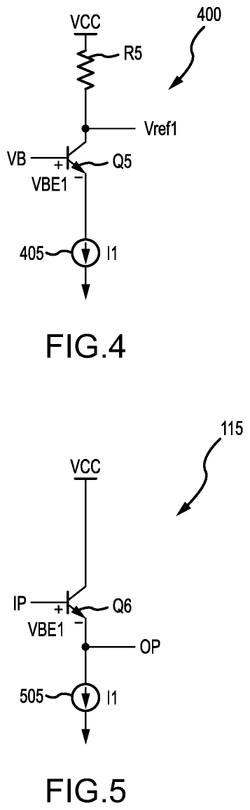

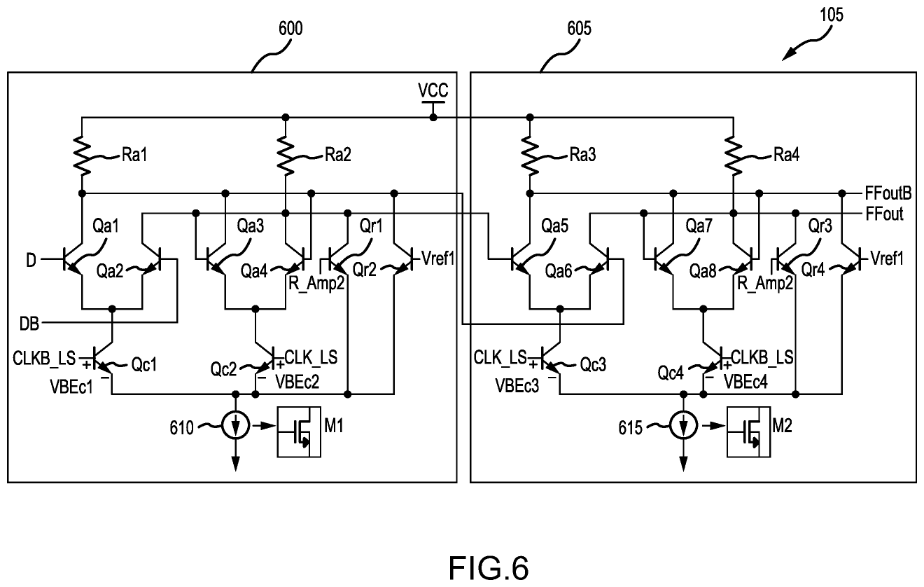

In an exemplary embodiment, and referring to FIGS. 1 and 6, the flip flop circuit 105 may be configured to provide data sampling and/or frequency division and generate a first flip flop output FFout and a second flip flop output FFoutB. In an exemplary embodiment, the flip flop circuit 105 may be configured as a D flip flop comprising a first input terminal to receive a first clock signal (i.e., a first clock signal terminal, Clock), a second input terminal to receive a second clock signal (i.e., a second clock signal terminal, ClockB), a third input terminal to receive a reset signal R (i.e., a reset terminal, Reset), and a fourth input terminal to receive a first reference voltage Vref1 (i.e., a reference voltage terminal, R_DC). The first reference voltage Vref1 may be external or internal to the system 100. The first reference voltage Vref1 may be generated by any suitable voltage generator circuit, such as the circuit illustrated in FIG. 4. In other embodiments, the flip flop circuit 105 may comprise any suitable flip flop type for the particular application or electronic device.

In an exemplary embodiment, the flip flop circuit 105 may comprise a first sub-circuit 600 and a second sub-circuit 605 that operate together to provide complementary modes, such as a hold mode and a track mode. When the first sub-circuit 600 is in the hold mode, the second sub-circuit 605 will be in the track mode, and vice versa. Both the first and second sub-circuits 600, 605 may be configured to receive a supply voltage VCC. The supply voltage VCC may be selected according to the particular application, desired operating specifications, and the like. In an exemplary embodiment, the supply voltage VCC is approximately 3.3V or less.

The first sub-circuit 600 may comprise a plurality of resistors, such as resistors Ra1 and Ra2. The first sub-circuit 600 may further comprise a plurality of transistors, such as transistors Qa1, Qa2, Qa3, Qa4, Qr1, Qr2, Qc1, and Qc2. Transistors Qa1, Qa2, Qa3, Qa4, Qr1, Qr2, Qc1, and Qc2 may comprise bipolar junction transistors or any other transistor type. The transistors Qa1, Qa2, Qa3, Qa4, Qr1, Qr2, Qc1, and Qc2 may be arranged to form three current steering amplifiers. Transistor Qa1 may be responsive to a data signal D, transistor Qa2 may be responsive to an inverted data signal DB, being an inverted version of the data signal D.

The first sub-circuit 600 may further comprise a first current source 610. The first current source 610 may be implemented with a transistor, such as transistor M1.

The second sub-circuit 605 may comprise a plurality of resistors, such as resistors Ra3 and Ra4. The second sub-circuit 605 may further comprise a plurality of transistors, such as transistors Qa5, Qa6, Qa7, Qa8, Qc3, Qc4, Qr3, and Qr4. Transistors Qa5, Qa6, Qa7, Qa8, Qc3, Qc4, Qr3, and Qr4 may comprise bipolar junction transistors or any other transistor type. The transistors Qa5, Qa6, Qa7, Qa8, Qc3, Qc4, Qr3, and Qr4 may be arranged to form three current steering amplifiers.

The second sub-circuit 605 may further comprise a second current source 615. The second current source 615 may be implemented with a transistor, such as transistor M2.

The first circuit path 125 may be configured to receive an input clock signal, such as a first input clock signal CLK and a second input clock signal CLKB. The second input clock signal CLKB may be an inverse of the first input clock signal CLK. In an exemplary embodiment, the first circuit path 125 may connect to the first and second terminals (Clock and ClockB) of the flip flop circuit 105.

In an exemplary embodiment, the first circuit path 125 generates a modified clock signal with a first high voltage value VIH1 that is equal to the supply voltage VCC minus the base-emitter voltage VBE (i.e., VIH1=VCC−VBE). In addition, the modified clock signal has a first low voltage value VIL1 that is equal to the supply voltage VCC minus the base-emitter voltage VBE minus a predetermined constant C (i.e., VIL1=VCC−VBE−C). Accordingly, the flip flop circuit 105 receives, at the first and second input terminals, the first high voltage value VIH1 and the first low voltage value VIL1.

In an exemplary embodiment, the first circuit path 125 may receive the first input clock signal CLK and the second input clock signal CLKB and modify the first and second input clock signals CLK, CLKB. For example, the first circuit path 125 may amplify the first input clock signal CLK and the second input clock signal CLKB and shift the voltage swing of each. In an exemplary embodiment, the first circuit path 125 may comprise a type-1 amplifier (also referred to as a “first-type amplifier”), such as a first type-1 amplifier 110(1).

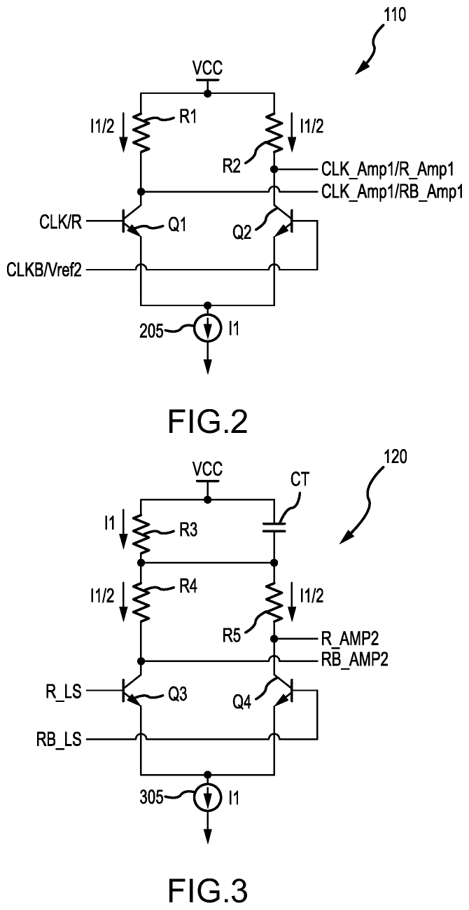

Referring to FIGS. 1 and 2, the type-1 amplifier 110 may be configured as a fully-differential amplifier. For example, the type-1 amplifier 110 may receive a data signal and the inverse data signal as inputs and generate a first output signal (e.g., outputs CLK_Amp1 and R_Amp1) and a second output signal (e.g., outputs CLKB_Amp1 and RB_Amp1). Input signals may be clock signals, such as the first input clock signal CLK and the second input clock signal CLKB if located in the first circuit path 125, or the reset signal R and a second reference voltage Vref2 if located in the second circuit path 130. Accordingly, output signals CLK_Amp1, CLKB_Amp1 are modified versions of the original input clock signals CLK and CLKB. In addition, output signals R_Amp1, RB_Amp1 are modified differential versions of the original reset input signal R. The high and low values of the output CLK_Amp1 may be defined as follows: CLK_Amp1_{HIGH}=VCC and CLK_Amp1_{LOW}=VCC−C. In addition, the high and low values of the output CLKB_Amp1 may be defined as follows: CLKB_Amp1_{HIGH}=VCC and CLKB_Amp1_{LOW}=VCC−C.

In one embodiment, the type-1 amplifier 110 may receive the supply voltage VCC and comprise a differential load resistor pair, such as resistor pair R1 and R2. Resistors R1 and R2 may have the same resistance R. The type-1 amplifier 110 may further comprise a first transistor Q1 connected in series with the first resistor R1, and a second transistor Q2 connected in series with the second resistor R2. Transistors Q1 and Q2 may comprise bipolar junction transistors, wherein each transistor comprises a base terminal, an emitter terminal, and a collector terminal. The first transistor Q1 may receive a data signal (e.g., CLK) at its base terminal. The second transistor Q2 may receive an inverse data signal (e.g., CLKB) at its base terminal. The type-1 amplifier 110 may further comprise a current source 205 connected to the emitter terminals of both transistors Q1 and Q2 and generating a current I1.

The predetermined constant C may be based on the specifications of the type-1 amplifier 110. For example, the constant C is the product of the current I1 and resistance R, and the current I1 and resistance R may be selected based on desired power and frequency performance. In an exemplary embodiment, the predetermined constant C is 0.2V.

Using the type-1 amplifier 110, as described above, in the first circuit path 125 may provide better headroom for the current source devices (i.e., transistors M1 and M2) used in the flip flop circuit 105.

Referring to FIGS. 1 and 5, the first circuit path 125 may further comprise a level-shifter circuit 115, such as a first level shifter circuit 115(1), to shift the voltage level of the input clock signals CLK, CLKB to provide a desired biasing to the flip flop transistors, in particular to transistors Qc1, Qc2, Qc3, and Qc4. In an exemplary embodiment, the first level shifter circuit 115(1) is connected in series with the first type-1 amplifier 110(1) and generates output clock signals CLK_LS and CLKB_LS, which are modified versions of the original input clock signals CLK and CLKB. In particular, input terminals of the first level shifter circuit 115(1) may be connected to output terminals of the first type-1 amplifier 110(1) and thus receive output signals CLK_Amp1 and CLKB_Amp1 as inputs. In addition, output terminals of the first level shifter circuit 115(1) may be connected to the first clock terminal (Clock) and the second clock terminal (ClockB) of the flip flop circuit 105, and thus provide the first high voltage value VIH1 and the first low voltage value VIL1 to the flip flop circuit 105. In other words, the modified clock signals CLK_LS and CLKB_LS are characterized by the first high voltage value VIH1 and the first low voltage value VIL1. The high and low values of the output CLK_LS may be defined as follows: CLK_LS_{HIGH}=VCC−VBE (where VBE is the base-emitter voltage of transistor Q6 of the level shifter circuit 115) and CLK_LS_{LOW}=VCC−VBE−C. In addition, the high and low values of the output CLKB_LS may be defined as follows: CLKB_LS_{HIGH}=VCC−VBE and CLKB_LS_{LOW}=VCC−VBE−C.

The level shifter circuit 115 may receive the supply voltage VCC and comprise a transistor Q6 connected in series with a current source 500. Transistor Q6 may comprise a bipolar junction transistor comprising a base terminal to receive an input signal IP, an emitter terminal connected to the current source 500, and a collector terminal connected to the supply voltage VCC. While the level shifter circuit 115 illustrated in FIG. 5 is single-ended, it is understood that the circuit could be modified to provide a fully differential level shifter circuit.

The second circuit path 130 may be configured to provide a reset signal, such as an external reset signal R to the flip flop circuit 105. In an exemplary embodiment, the second circuit path 130 may be configured to receive the reset signal R and connected to the third input terminal (Reset). The second circuit path 130 may receive and operate according to the second reference voltage Vref2.

In an exemplary embodiment, the second circuit path 130 generates a modified reset signal having a second high voltage value VIH2 that is greater than the first high voltage value VIH1 (i.e., VIH2>VIH1) and a second low voltage value VIL2 that is less than the first low voltage value VIL1 (i.e., VIL2<VIL1) to ensure proper functionality of the flip flop circuit 105 during normal operation and RESET mode. For example, the second high voltage value VIH2 may be greater than the first high voltage value VIH1 by 150 mV and the second low voltage value VIL2 may be less than the first low voltage value VIL1 by 150 mV.

In an exemplary embodiment, the second high voltage value is equal to the supply voltage VCC minus the base-emitter voltage VBE plus a second predetermined constant C2, such as 0.2V (i.e., VIH2=VCC−VBE+0.2V). In addition, the second low voltage value VIL2 is equal to the supply voltage VCC minus the base-emitter voltage VBE minus a third predetermined constant C3, such as 0.4V (i.e., VIL1=VCC−VBE−0.4V). In other words, the second high voltage value VIH2 is equal to the first high voltage value VIH1 plus 0.2V (i.e., VIH2=VIH1+0.2V) and the second low voltage value VIL2 is equal to the first low voltage value VIL1 minus 0.2V (i.e., VIL2=VIL1−0.2V). Constants C2 and C3 may be selected to be any value as long as VIH2 is greater than VIH1 and VIL2 is less than VIL1. Accordingly, the flip flop circuit 105 receives, at the third input terminal (Reset), the second high voltage value VIH2 and the second low voltage value VIL2.

In an exemplary embodiment, the second circuit path 130 may receive and modify the reset signal R and the second reference voltage Vref2. For example, the second circuit path 130 may amplify the reset signal R and shift the voltage.

In an exemplary embodiment, the second circuit path 130 may comprise a second type-1 amplifier 110(2) and a type-2 amplifier 120 (also referred to as a “second-type amplifier”). The second type-1 amplifier 110(2) may be identical (in regards to structure and function) to the first type-1 amplifier 110(1) described above and receive the reset signal R at a first input terminal and the second reference voltage Vref2 at a second input terminal and generate output signals R_Amp1 and RB_Amp1, which are modified versions of the reset signal R. The high and low values of the output R_Amp1 may be defined as follows: R_Amp1_{HIGH}=VCC and R_Amp1_{LOW}=VCC−C (e.g., C=0.2V). In addition, the high and low values of the output RB_Amp1 may be defined as follows: RB_Amp1_{HIGH}=VCC and RB_Amp1_{LOW}=VCC−C (e.g., C=0.2V).

The second circuit path 130 may further comprise a second level shifter circuit 115(2). The second level shifter circuit 115(2) may be identical (in regards to structure and function) to the first level shifter circuit 115(1) described above and generate output signals R_LS and RB_LS (which are modified versions of the reset signal R and second reference voltage Vref2, respectively) to provide a desired biasing to the flip flop transistors, in particular, transistors Qr1 and Qr3. The high and low values of the output R_LS may be defined as follows: R_LS_{HIGH}=VCC−VBE and R_LS_{LOW}=VCC−VBE−C (e.g., C=0.2V). In addition, the high and low values of the output RB_LS may be defined as follows: RB_LS_{HIGH}=VCC−VBE and RB_LS_{LOW}=VCC−VBE−C (e.g., C=0.2V).

In an exemplary embodiment, the second type-1 amplifier 110(2), the second level shifter circuit 115(2), and the type-2 amplifier 120 may be connected in series with each other, wherein the second level shifter 115(2) may be connected between the second type-1 amplifier 110(2) and the type-2 amplifier 120. As such, the second level shifter circuit 115(2) receives output signals R_Amp1 and RB_Amp1 as inputs, and the type-2 amplifier 120 receives output signals R_LS and RB_LS as inputs. In addition, an output terminal of the type-2 amplifier 120 may be connected to the reset terminal (Reset) of the flip flop circuit 105.

In an exemplary embodiment, and referring to FIGS. 1 and 3, the type-2 amplifier 120 may further amplify the reset signal R. The type-2 amplifier 120 may be configured as a differential amplifier. For example, the type-2 amplifier 120 may receive a data signal and the inverse data signal as inputs and generate an output signal (e.g., output R_Amp2) that is a modified version of the original reset signal R.

In one embodiment, the type-2 amplifier 120 may receive the supply voltage VCC and comprise a third resistor R3 in parallel with a capacitor CT. The type-2 amplifier 120 may further comprise a fourth resistor R4 in series with the third resistor R3 and a fifth resistor R5 in series with the third resistor R3. The type-2 amplifier 120 may further comprise a third transistor Q3 connected in series with the fourth resistor R4, and a fourth transistor Q4 connected in series with the fifth resistor R5. Transistors Q3 and Q4 may comprise bipolar junction transistors, wherein each transistor comprises a base terminal, an emitter terminal, and a collector terminal. The third transistor Q3 may receive a data signal (e.g., signal R_LS) at its base terminal. The fourth transistor Q4 may receive an inverse data signal (e.g., signal RB_LS) at its base terminal. The type-2 amplifier 120 may further comprise a current source 305 connected to the emitter terminals of transistors Q3 and Q4.

In addition, an output terminal of the type-2 amplifier 120 may be connected to the third input terminal (Reset) of the flip flop circuit 105, and thus the type-2 amplifier 120, in conjunction with the second type-1 amplifier 110(2) and second level shifter circuit 115(2), provides the second high voltage value VIH2 and the second low voltage value VIL2 to the flip flop circuit 105. In other words, the modified reset signal R_Amp2 is characterized by the second high voltage value VIH2 and the second low voltage value VIL2. As such, the high and low values of the output R_Amp2 may be defined as follows: R_Amp2_{HIGH}=VIH2=VCC−VBE+0.2V and R_Amp2_{LOW}=VIL2=VCC−VBE−0.4V.

Using a type-2 amplifier at the end of the second circuit path 130 may provide the flip flop circuit 105 with more precise levels of the modified reset signals R_Amp2_{HIGH} and R_Amp2_{LOW}.

According to an exemplary embodiment, and referring to FIGS. 1 and 4, the system 100 may further comprise a reference voltage generator circuit 400 to generate a reference voltage Vref1. For example, the reference voltage generator circuit 400 may comprise a fifth resistor R5 connected to the supply voltage VCC, a fifth transistor Q5 connected in series with the resistor R5, and a current source 405 connected to a terminal of transistor Q5. Transistor Q5 may comprise a bipolar junction transistor comprising a base terminal, an emitter terminal, and a collector terminal. In one embodiment, the emitter terminal of transistor Q5 may be connected to the current source 405 and a constant voltage VB may be connected to the base terminal. In an exemplary embodiment, the constant voltage VB is equal to the supply voltage VCC but may be any voltage that keeps transistor Q5 in its active region of operation.

In an exemplary embodiment, the reference voltage generator circuit 400 may be configured to ensure that the first reference voltage Vref1 is the same level (voltage value) as the second low voltage value VIL2 (i.e., Vref1=VIL2) so that the transistors Qr1, Qr2, Qr3, and Qr4 do not affect the output signal of the flip flop circuit 105 during normal data propagation (normal operation).

Various embodiments of the present technology may be implemented using BiCMOS, CMOS, or other any technology.

Various embodiments of the present technology achieve high speed performance at lower supply voltages, meeting DC biasing requirements of the current source device (for flip flops).

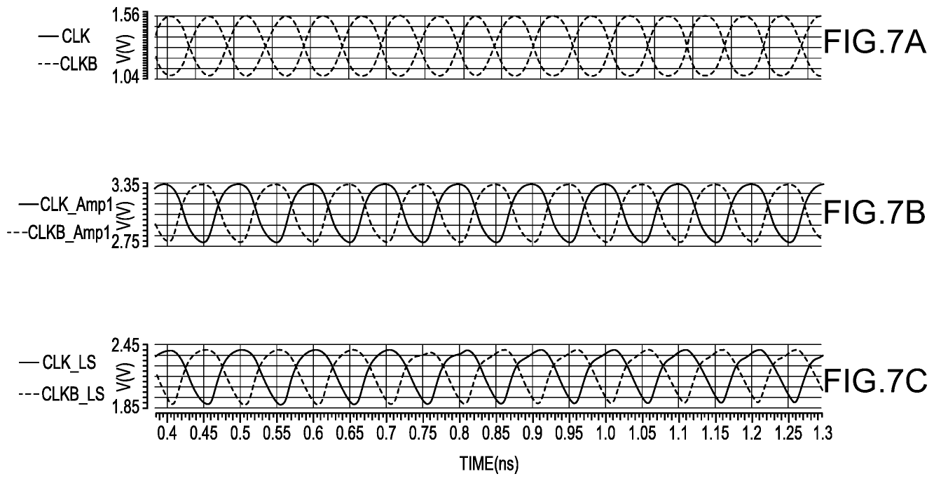

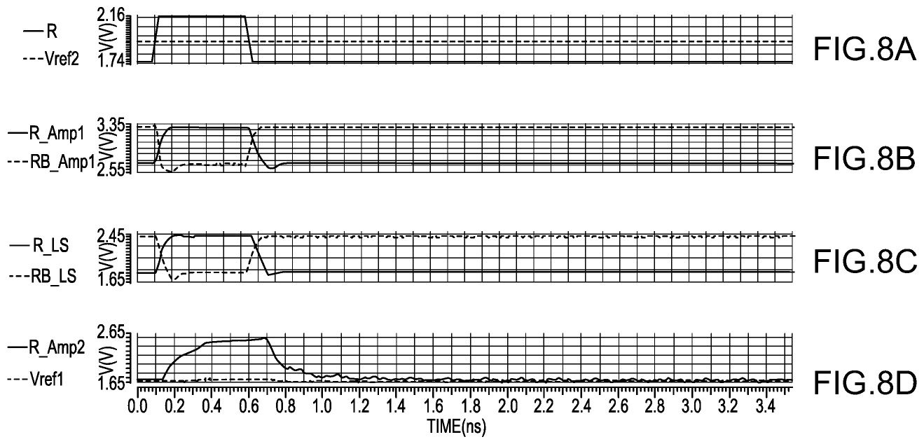

In operation, and referring to FIGS. 1, 7A-7C, and 8A-8D, the first circuit path 125 may receive input clock signals CLK and CLKB. The first type-1 amplifier 110(1) may modify the original input clock signals CLK and CLKB by amplifying the signals and generating modified clock signals CLK_Amp1 and CLKB_Amp1. The first type-1 amplifier 110(1) may then transmit the modified clock signals CLK_Amp1 and CLKB_Amp1 to the first level shifter circuit 115(1), wherein the first level shifter circuit 115(1) further modifies the clock signal by shifting the voltage of the input signals (i.e., CLK_Amp1 and CLKB_Amp1) and generating modified clock signals CLK_LS and CLKB_LS. The first level shifter circuit 115(1) may then transmit the modified clock signals CLK_LS and CLKB_LS to the clock terminals (Clock and ClockB) of the flip flop circuit 105, wherein the flip flop circuit 105 operates according to the modified clock signals CLK_LS and CLKB_LS having the first high voltage value VIH1 (e.g., ˜2.4V) and the first low voltage value VIL1 (e.g., ˜1.85V).

At the same time that the first circuit path 125 receives and modifies the input clock signals CLK and CLKB, the second circuit path 130 may receive the reset signal R and the second reference voltage Vref2. The second type-1 amplifier 110(2) may modify the original reset signal R by amplifying the signal and generating modified reset signals R_Amp1 and RB_Amp1. The second type-1 amplifier 110(2) may then transmit the modified reset signals R_Amp1 and RB_Amp1 to the second level shifter circuit 115(2), wherein the second level shifter circuit 115(2) further modifies the reset signal by shifting the voltage of the input signals (i.e., R_Amp1 and RB_Amp1) and generating modified reset signals R_LS and RB_LS. The second level shifter circuit 115(2) may then transmit the modified reset signals R_LS and RB_LS to the type-2 amplifier 120. The type-2 amplifier 120 may further modify the original reset signal R by amplifying the signal and generating modified reset signals R_Amp2 and RB_Amp2. The type-2 amplifier 120 may then transmit the modified reset signals R_Amp2 to the reset terminal (RESET) of the flip flop circuit 105, wherein the flip flop circuit 105 operates according to the modified reset signal R_Amp2 having the second high voltage value VIH2 (e.g., ˜2.6V, which is greater than the first high voltage value VIH1), and the second low voltage value VIL2 (e.g., ˜1.65V, which is less than the first low voltage value VIL1), and the first reference voltage Vref1.

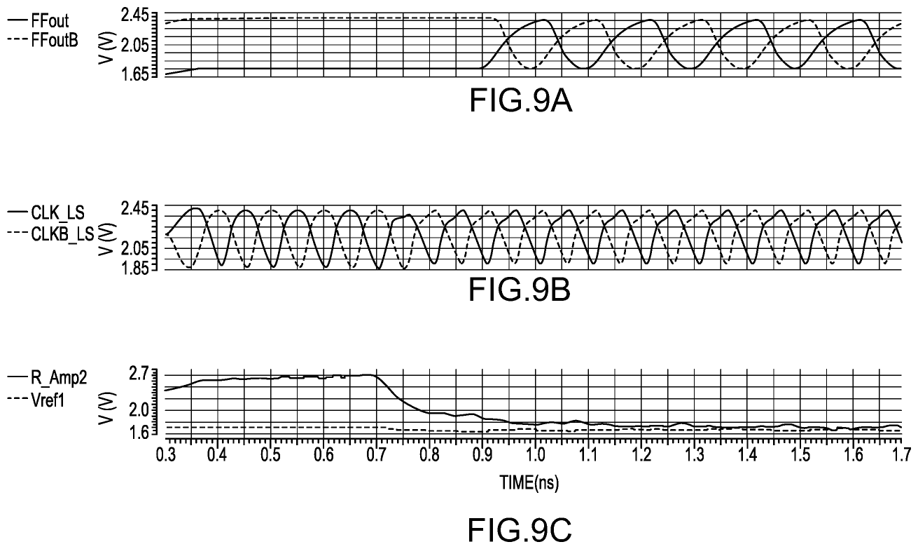

Referring to FIGS. 9A-9C, the flip flop circuit 105 may be used as a frequency divider—in this case to divide by 2. When the signal at the reset terminal is HIGH (i.e., R_Amp2), the first flip flop output FFout is LOW and the second flip flop output FFoutB is HIGH. When the signal at the reset terminal is LOW, the flip flop circuit 105 generates outputs with a frequency of 5 GHz when configured in the divide-by-2 mode and with the clock signal having a clock frequency of 10 GHz.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

1. A system, comprising:
a flip flop circuit comprising a first input terminal and a second input terminal;
a first circuit path connected to the first input terminal and comprising a first type-1 amplifier connected in series with a first level shifter circuit; and
a second circuit path connected to the second input terminal and comprising a second type-1 amplifier connected in series with a second level shifter circuit and a type-2 amplifier.

2. The system according to claim 1, wherein the type-1 amplifier comprises a first current path and a second current path in parallel with the first current path; wherein the first current path comprises a first resistor connected in series with a first transistor, and the second current path comprises a second resistor connected in series with a second transistor.

3. The system according to claim 2, wherein:
the first and second current paths are configured to connect to a voltage source; and
the type-1 amplifier further comprises a current source connected to the first and second current paths.

4. The system according to claim 1, wherein the type-2 amplifier comprises a first current path and a second current path in parallel with the first current path; wherein the first current path comprises a first resistor, a second resistor in series with the first resistor, and a first transistor in series with the second resistor, and the second current path comprises a capacitor in parallel with the first resistor, a third resistor in series with the first resistor, and a second transistor in series with the third resistor.

5. The system according to claim 4, wherein the first and second current paths are configured to connect to a voltage source and the type-2 amplifier comprises a current source connected to the first and second current paths.

6. The system according to claim 1, wherein the first level shifter circuit is connected to an output terminal of the first type-1 amplifier.

7. The system according to claim 1, wherein:
the second level shifter circuit is connected to an output terminal of the second type-1 amplifier; and
the type-2 amplifier is connected to an output terminal of the second level shifter circuit.

8. The system according to claim 1, wherein:
the first circuit path generates a clock signal with a first high voltage value and a first low voltage value;
the second circuit path generates a reset signal with a second high voltage value and a second low voltage value;
the second high voltage value is greater than the first high voltage value; and
the second low voltage value is less than the first low voltage value.

9. The system according to claim 1, wherein the flip flop circuit further comprises:
a first sub-circuit configured to operate in a track mode and comprising a first transistor that functions as a first current source; and
a second sub-circuit configured to operate in a hold mode and comprising a second transistor that functions as a second current source.

10. A method for operating a flip flop circuit connected to a first circuit path at a first input terminal and a second circuit path at a second input terminal, comprising:
applying a supply voltage value to the flip flop circuit; and
generating, with the first circuit path, a clock signal having a first high voltage value and a first low voltage value; and
generating, with the second circuit path, a reset signal having a second high voltage value that is greater than the first high voltage value and a second low voltage value that is less than the first low voltage value.

11. The method according to claim 10, wherein the first circuit path comprises a first type-1 amplifier and a first level shifter circuit directly connected to an output terminal of the first type-1 amplifier and directly connected to the first input terminal.

12. The method according to claim 11, wherein the second circuit path comprises a second type-1 amplifier, a second level shifter circuit connected to an output terminal of the second type-1 amplifier, and a type-2 amplifier directly connected to an output terminal of the second level shifter circuit and directly connected to the second input terminal.

13. The method according to claim 12, wherein:
the type-1 amplifier comprises a first current path and a second current path in parallel with the first current path; wherein the first current path comprises a first resistor connected in series with a first transistor, and the second current path comprises a second resistor connected in series with a second transistor; and
the type-2 amplifier comprises a first current path and a second current path in parallel with the first current path; wherein the first current path comprises a first resistor, a second resistor in series with the first resistor, and a first transistor in series with the second resistor, and the second current path comprises a capacitor in parallel with the first resistor, a third resistor in series with the first resistor, and a second transistor in series with the third resistor.

14. A system, comprising:
a flip flop circuit configured to connect to a voltage source having a supply voltage value and comprising:
a first input terminal and a second input terminal;
a first sub-circuit connected to the first and second input terminals and comprising a first transistor that functions as a first current source and a second transistor having a base-emitter voltage value; and
a second sub-circuit connected to the first and second input terminals and comprising a third transistor that functions as a second current source and a fourth transistor having the base-emitter voltage value; and
a first circuit path connected to the first input terminal, wherein the first circuit path is configured to generate a clock signal having a first high voltage value and a first low voltage value; and
a second circuit path connected to the second input terminal, wherein the second circuit path is configured to generate a reset signal having:
a second high voltage value that is greater than the first high voltage value; and
a second low voltage value that is less than the first low voltage value.

15. The system according to claim 14, wherein the first circuit path comprises a first type-1 amplifier and a first level shifter circuit connected to an output terminal of the first type-1 amplifier.

16. The system according to claim 15, wherein the type-1 amplifier comprises a first current path and a second current path in parallel with the first current path; wherein the first current path comprises a first resistor connected in series with a first transistor, and the second current path comprises a second resistor connected in series with a second transistor.

17. The system according to claim 14, wherein the second circuit path comprises a second type-1 amplifier, a second level shifter circuit connected to an output terminal of the second type-1 amplifier, and a type-2 amplifier connected to an output terminal of the second level shifter circuit.

18. The system according to claim 17, wherein the type-2 amplifier comprises a first current path and a second current path in parallel with the first current path; wherein the first current path comprises a first resistor, a second resistor in series with the first resistor, and a first transistor in series with the second resistor, and the second current path comprises a capacitor in parallel with the first resistor, a third resistor in series with the first resistor, and a second transistor in series with the third resistor.

19. The system according to claim 14, wherein:
the first high voltage value is equal to a supply voltage value minus the base-emitter voltage value; and
the first low voltage value is equal to the supply voltage value minus the base-emitter voltage value minus a predetermined constant.

20. The system according to claim 14, wherein:
the second high voltage value is equal to the first high voltage value plus a predetermined constant; and
the second low voltage value is equal to the first low voltage value minus the predetermined constant.
